(19) United States
(12) Patent Application Publication
(10) Pub. No.: US 2025/0024682 A1
(43) Pub. Date: Jan. 16, 2025

(54) SEMICONDUCTOR DEVICE

(71) Applicant: Samsung Electronics Co., Ltd., Suwon-si (KR)

(72) Inventors: Rokgyeong Kim, Suwon-si (KR); Myunghun Lee, Suwon-si (KR)

(21) Appl. No.: 18/626,466

(22) Filed: Apr. 4, 2024

(30) Foreign Application Priority Data
Jul. 14, 2023 (KR) 10-2023-0091934

(51) Int. Cl. H10B 43/40; G11C 16/08; H10B 41/27; H10B 41/41; H10B 43/27

(52) U.S. Cl. CPC H10B 43/40; H10B 41/27; H10B 41/41; H10B 43/27; G11C 16/08

(57) ABSTRACT

A semiconductor device may include a peripheral circuit region including a plurality of elements on a substrate, the plurality of elements providing a page buffer and a row decoder, wherein the peripheral circuit region includes a first well region and a second well region, and at least one of a conductivity-type of impurities or a doping concentration of the first well region is different from that of the second well region, wherein the row decoder includes at least one first element in the first well region, and at least one second element in the second well region, wherein the first well region and the second well region are configured to have a same body bias voltage, and wherein the first well region is in contact with the second well region in a second direction parallel to an upper surface of the substrate.

### CROSS-REFERENCE TO RELATED APPLICATION(S)

This application claims benefit of priority to Korean Patent Application No. 10-2023-0091934 filed on Jul. 14, 2023, in the Korean Intellectual Property Office, the disclosure of which is incorporated herein by reference in its entirety.

### BACKGROUND

The present disclosure relates to a semiconductor device.

A semiconductor device may include a cell region in which memory cells for storing data are disposed, and a peripheral circuit region in which circuits for controlling the cell region are disposed. The peripheral circuit region may include a row decoder, a page buffer, a voltage generator, and a control logic circuit, and the row decoder may be connected to the cell region through word lines, ground select lines, and string select lines. In order to improve the degree of integration of a semiconductor device, various methods have been proposed to increase the degree of integration of cell regions as well as peripheral circuit regions.

### SUMMARY

An aspect of the present disclosure is to provide a semiconductor device having improved integration by eliminating a gap between a first well region and a second well region in which a body bias voltage having the same size is input in a peripheral circuit region and bringing the first well region into contact with the second well region.

According to some aspects of the present disclosure, a semiconductor device may include a peripheral circuit region including a plurality of elements on a substrate, the plurality of elements providing a page buffer and a row decoder, and a cell region including gate electrode layers and channel structures, wherein the gate electrode layers are stacked in a first direction perpendicular to an upper surface of the substrate and are connected to the row decoder, and wherein the channel structures extend into the gate electrode layers in the first direction and are connected to the page buffer, wherein the peripheral circuit region includes a first well region and a second well region, and at least one of a conductivity-type of impurities or a doping concentration of the first well region is different from that of the second well region, wherein the row decoder includes at least one first element among the plurality of elements in the first well region, and at least one second element among the plurality of elements in the second well region, wherein the first well region and the second well region are configured to have a same body bias voltage, and wherein the first well region and the second well region are adjacent to each other in a second direction parallel to the upper surface of the substrate, and the first well region is in contact with the second well region in the second direction.

According to some aspects of the present disclosure, a semiconductor device may include a peripheral circuit region including a substrate and first and second elements on the substrate, wherein the substrate includes a first well region doped with a first concentration of impurities having a first conductivity-type and a second well region doped with a second concentration of impurities having a second conductivity-type, and a cell region including gate electrode layers and channel structures, wherein the gate electrode layers are stacked in a first direction perpendicular to an upper surface of the substrate, and wherein the channel structures extend into the gate electrode layers in the first direction, wherein the first well region and the second well region are configured to have a same body bias voltage, and wherein the first well region is in contact with the second well region in a second direction parallel to the upper surface of the substrate.

According to some aspects of the present disclosure, a semiconductor device may include a substrate including a first well region and a second well region, wherein at least one of a conductivity-type of impurities or a doping concentration of the first well region is different from that of the second well region, a plurality of first elements in the first well region, and a plurality of second elements in the second well region, wherein the first well region and the second well region are configured to have a same body bias voltage, and wherein the first well region is in contact with the second well region.

According to some example embodiments of the present disclosure, a first well region and a second well region which are formed in a peripheral circuit region and receive the same voltage as a body bias voltage may be formed to be in contact with each other. Accordingly, the degree of integration of a semiconductor device may be improved by improving the degree of integration of the elements formed in the peripheral circuit region.

Advantages and effects of the present application are not limited to the foregoing content and may be more easily understood in the process of describing example embodiments of the present disclosure.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a block diagram schematically illustrating a semiconductor device according to some example embodiments of the present disclosure;

FIG. 2 is a diagram schematically illustrating a structure of a semiconductor device according to some example embodiments of the present disclosure;

FIG. 3 is a circuit diagram schematically illustrating a memory block of a semiconductor device according to some example embodiments of the present disclosure;

FIG. 4 is a view schematically illustrating arrangements of a cell region and a peripheral circuit region in a semiconductor device according to some example embodiments of the present disclosure; and

FIG. 5 is a diagram illustrating a structure of a semiconductor device according to some example embodiments of the present disclosure;

FIG. 6 is a view illustrating a cross-section taken along line I-I′ of the semiconductor device illustrated in FIG. 5 according to some example embodiments of the present disclosure;

FIG. 7 is a diagram illustrating a structure of a semiconductor device according to some example embodiments of the present disclosure;

FIG. 8 is a view illustrating a cross-section taken along line II-II′ of the semiconductor device illustrated in FIG. 7 according to some example embodiments of the present disclosure;

FIG. 9 is a view schematically illustrating a row decoder according to some example embodiments of the present disclosure;

FIG. 10 is a circuit diagram schematically illustrating a row decoder according to some example embodiments of the present disclosure;

FIG. 11 is a view schematically illustrating a structure of a semiconductor device according to some example embodiments of the present disclosure;

FIG. 12 is a view illustrating a structure of a semiconductor device according to some example embodiments of the present disclosure;

FIGS. 13 and 14 are views illustrating a cross-section taken along line III-III′ of the semiconductor device of FIG. 12 according to some example embodiments of the present disclosure;

FIG. 15 is a view schematically illustrating a structure of a semiconductor device according to some example embodiments of the present disclosure;

FIGS. 16 and 17 are views illustrating a structure of a semiconductor device according to some example embodiments of the present disclosure; and

FIG. 18 is a block diagram schematically illustrating a storage device including a semiconductor device according to some example embodiments of the present disclosure.

### DETAILED DESCRIPTION

Hereinafter, example embodiments of the present disclosure will be described with reference to the accompanying drawings.

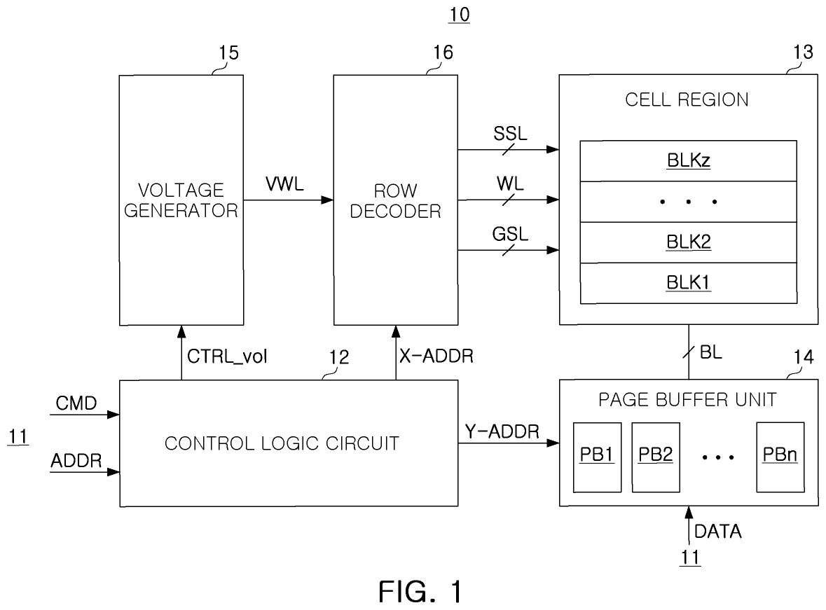

FIG. 1 is a block diagram schematically illustrating a semiconductor device according to some example embodiments of the present disclosure.

Referring to FIG. 1, a semiconductor device 10 may include a control logic circuit 12, a cell region 13, a page buffer unit 14, a voltage generator 15, and a row decoder 16. The semiconductor device 10 may further include an interface circuit 11, and may further include a column logic, a pre-decoder, a temperature sensor, a command decoder, an address decoder, and a source driver. The semiconductor device 10 may be a memory device for storing data, for example, a non-volatile memory device in which stored data is maintained even when power is cut off.

The control logic circuit 12 may generally control various operations in the semiconductor device 10. The control logic circuit 12 may output various control signals in response to a command CMD and/or an address ADDR received from the interface circuit 11. For example, the control logic circuit 12 may output a voltage control signal CTRL_vol, a row address X-ADDR, and a column address Y-ADDR.

The cell region 13 may include a plurality of memory blocks BLK1-BLKz (where z is a positive integer), and each of the plurality of memory blocks BLK1-BLKz may include a plurality of memory cells. For example, the plurality of memory blocks BLK1-BLKz may include main blocks for storing data and at least one spare block for storing data necessary for an operation of the semiconductor device 10. The cell region 13 may be connected to a page buffer unit 14 through bit lines BL, and may be connected to the row decoder 16 through word lines WL, string select lines SSL, and ground select lines GSL. As used herein, “an element A connected to an element B” (or similar language) means that the element A is physically and/or electrically connected to the element B.

In some example embodiments, the cell region 13 may include a three-dimensional (3D) memory cell array, and the 3D memory cell array may include a plurality of NAND strings. Each NAND string may include memory cells connected to word lines vertically stacked on a substrate. In some other example embodiments, the cell region 13 may include a two-dimensional memory cell array, and the two-dimensional memory cell array may include a plurality of NAND strings disposed in row and column directions.

The page buffer unit 14 may include a plurality of page buffers PB1-PBn (where n is an integer of 3 or more), and the plurality of page buffers PB1-PBn may be connected to memory cells through a plurality of bit lines BL, respectively. The page buffer unit 14 may select at least one bit line among the bit lines BL in response to the column address Y-ADDR. The page buffer unit 14 may operate as a write driver or a sense amplifier according to an operating mode. For example, during a write operation, the page buffer unit 14 may apply a bit line voltage corresponding to the data to be programmed, to the selected bit line. During a read operation, the page buffer unit 14 may detect data stored in the memory cell by sensing a current or voltage of the selected bit line. The data to be programmed in the cell region 13 with the write operation and the data read from the cell region 13 with the read operation may be input and output through the interface circuit 11.

The voltage generator 15 may generate various types of voltages for performing write, read, and erase operations based on the voltage control signal CTRL_vol. For example, the voltage generator 15 may generate a write voltage, a read voltage, a pass voltage, a write verification voltage, and an erase voltage. In some example embodiments, the control logic circuit 12 may control the voltage generator 15 to generate a voltage for executing write, read, and erase operations using data stored in a spare block. Some of the voltages generated by the voltage generator 15 may be input to the word lines WL as a word line voltage VWL by the row decoder 16, and others may be input to a common source line by the source driver.

The row decoder 16 may select one of a plurality of word lines WL in response to the row address X-ADDR, and may select one of a plurality of string select lines SSL. For example, the row decoder 16 may apply a write voltage and a write verification voltage to the selected word line during the write operation and may apply the read voltage to the selected word line during the read operation.

The row decoder 16 may include a plurality of elements, and may include first elements formed in a first well region and second elements formed in a second well region. Each of the first and second well regions may be doped with impurities of the same conductivity-type, but doping concentrations thereof may be different from each other. Different body bias voltages may be applied to each of the first and second well regions, and a gap may be required between the well regions according to the Layout-Design-Rules. According to some example embodiments of the present disclosure, a body bias voltage having the same size may be applied to each of the first and second well regions, thereby omitting the gap between the well regions. In other words, a same body bias voltage may be applied to each of the first and second well regions, thereby omitting the gap between the well regions. Accordingly, since the first and second well regions may be in contact with each other and continuously disposed, the degree of integration of the row decoder 16 may be improved.

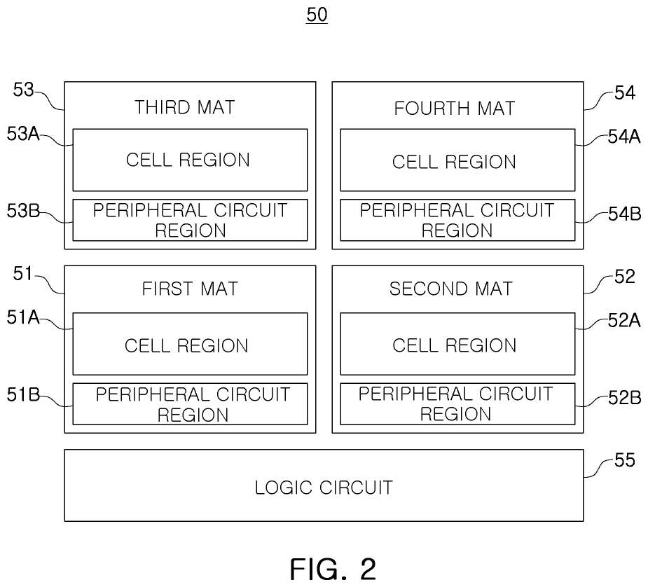

FIG. 2 is a view schematically illustrating a structure of a semiconductor device according to some example embodiments of the present disclosure.

Referring to FIG. 2, a semiconductor device 50 according to some example embodiments of the present disclosure may include a plurality of mats 51 to 54 and a logic circuit 55. For example, each of the plurality of mats 51 to 54 may include a cell region 13, a page buffer unit 14, and a row decoder 16 described with reference to FIG. 1, and the logic circuit 55 may include a control logic circuit 12 and a voltage generator 15 described with reference to FIG. 1.

According to example embodiments, each of the plurality of mats 51 to 54 may operate independently of each other. For example, while a first mat 51 executes a write operation of recording data received from an external memory controller, the logic circuit 55 may read data stored in a second mat 52 and output the data to the outside (e.g., to an external device).

Each of the plurality of mats 51 to 54 may include cell regions 51A, 52A, 53A and 54A and peripheral circuit regions 51B, 52B, 53B and 54B. The cell regions 51A, 52A, 53A and 54A may include memory cells, and the peripheral circuit regions 51B, 52B, 53B and 54B may include circuits for controlling the cell regions 51A, 52A, 53A and 54A, such as a row decoder and a page buffer unit.

In some example embodiments, the cell regions 51A, 52A, 53A and 54A of each of the plurality of mats 51 to 54 may include a plurality of blocks. As described above with reference to FIG. 1, the plurality of blocks may include main blocks for storing data and outputting the data in response to commands from the logic circuit 55, and spare blocks for storing data necessary for an operation of the semiconductor device 50.

The peripheral circuit regions 51B, 52B, 53B and 54B may include first elements formed in the first well region and second elements formed in the second well region. Each of the first and second well regions may be doped with impurities of the same conductivity-type, but doping concentrations thereof may be different from each other. When different body bias voltages are applied to each of the first and second well regions, interference between the first element and the second element may be prevented by placing a gap between the well regions. In some example embodiments of the present disclosure, the first and second well regions may be in contact with each other by applying the same body bias voltage to each of the first and second well regions. Accordingly, the degree of integration of the peripheral circuit regions 51B, 52B, 53B and 54B may be improved.

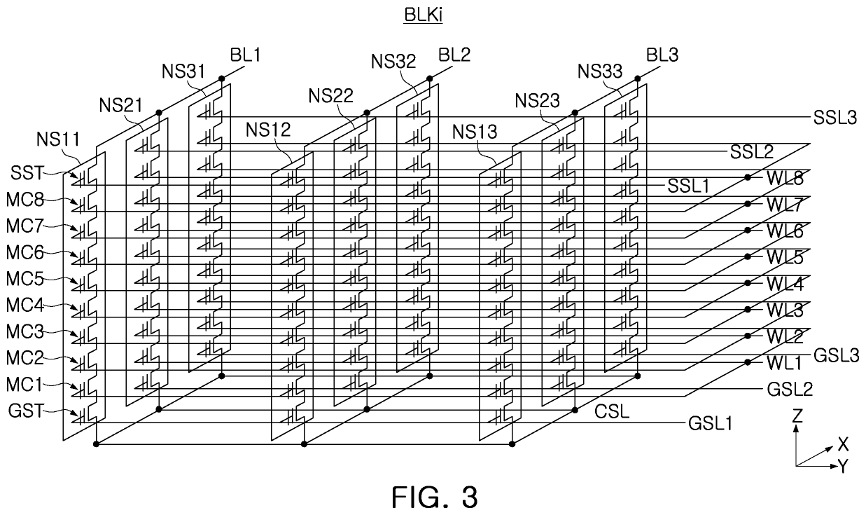

FIG. 3 is a circuit diagram schematically illustrating a memory block of a semiconductor device according to some example embodiments of the present disclosure.

A memory block BLKi illustrated in FIG. 3 represents a three-dimensional memory block formed in a three-dimensional structure on a substrate. For example, a plurality of NAND strings NS11 to NS33 included in the memory block BLKi may be formed in a direction that is perpendicular to the substrate (i.e., a Z-axis direction in FIG. 3).

Referring to FIG. 3, the memory block BLKi may include the plurality of NAND strings NS11 to NS33 connected between bit lines BL1, BL2 and BL3 and a common source line CSL. Each of the plurality of NAND strings NS11 to NS33 may include a string selection transistor SST, a plurality of memory cells MC1, MC2, . . . , MC8, and a ground selection transistor GST. Although FIG. 3 illustrates that each of the plurality of memory NAND strings NS11 to NS33 includes eight memory cells MC1, MC2, . . . , MC8, the present disclosure is not limited thereto.

A string selection transistor SST may be connected to corresponding string select lines SSL1, SSL2 and SSL3. The plurality of memory cells MC1, MC2, . . . , and MC8 may be connected to corresponding word lines WL1, WL2, . . . , and WL8, respectively. According to example embodiments, at least one of the word lines WL1, WL2, . . . , and WL8 may be provided as a dummy word line. A ground selection transistor GST may be connected to corresponding ground select lines GSL1, GSL2 and GSL3. The string selection transistor SST may be connected to corresponding bit lines BL1, BL2 and BL3, and the ground selection transistor GST may be connected to a common source line CSL.

Word lines of the same height (e.g., WL1) may be commonly connected, and the ground select lines GSL1, GSL2 and GSL3 and the string select lines SSL1, SSL2 and SSL3 may be separated from each other, respectively. In FIG. 3, the memory block BLKi is illustrated to be connected to eight word lines WL1, WL2, . . . , WL8 and three bit lines BL1, BL2 and BL3, but the present disclosure is not limited thereto.

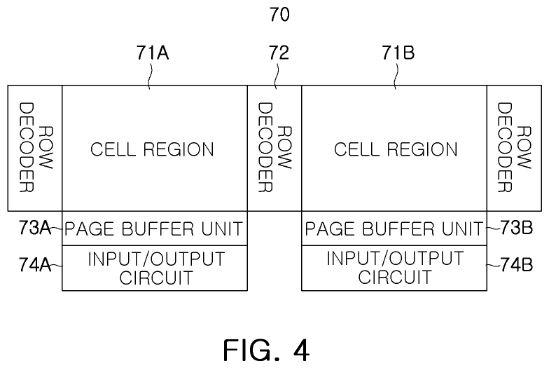

FIG. 4 is a view schematically illustrating arrangements of a cell region and a peripheral circuit region in a semiconductor device according to some example embodiments of the present disclosure.

In particular, FIG. 4 is a view illustrating the arrangement of the cell region and the peripheral circuit region in one of the mats included in a semiconductor device 70 according to some example embodiments of the present disclosure. Referring to FIG. 4, a peripheral circuit region may be disposed around cell regions 71A and 71B, and for example, the row decoder 72 may be disposed on both sides of each of the cell regions 71A and 71B. Meanwhile, the page buffer units 73A and 73B may be disposed below the cell regions 71A and 71B, respectively. The row decoder 72 and the page buffer units 73A and 73B may be connected to a logic circuit for controlling an overall operation of the semiconductor device 70, and an input/output interface for communicating with an external device, through input/output circuits 74A and 74B.

For example, word lines included in each of the cell regions 71A and 71B may extend horizontally and be connected to the row decoder 72 disposed adjacently to the cell regions 71A and 71B. Meanwhile, bit lines included in each of the cell regions 71A and 71B may extend vertically and be connected to the page buffer units 73A and 73B disposed below each of the cell regions 71A and 71B. In an example embodiment illustrated in FIG. 4, the cell regions 71A and 71B, the row decoder 72, the page buffer units 73A and 73B, and the input/output circuits 74A and 74B may be formed on a single substrate.

According to some example embodiments of the present disclosure, the row decoder 72 may include a substrate, a plurality of first elements, and a plurality of second elements. The substrate may include a first well region and a second well region in which at least one of a conductivity-type of impurities or a doping concentration is different. The plurality of first elements may be formed in the first well region, and the plurality of second elements may be formed in the second well region. A body bias voltage of the first well region and a body bias voltage of the second well region may be applied equally, and in this case, the first well region may be in contact with the second well region. Accordingly, the degree of integration of the semiconductor device 70 may be improved.

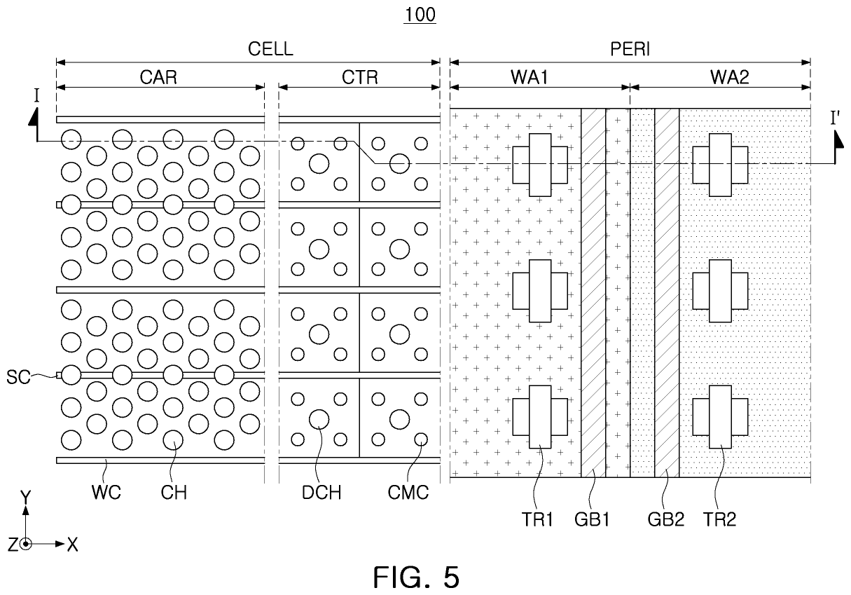

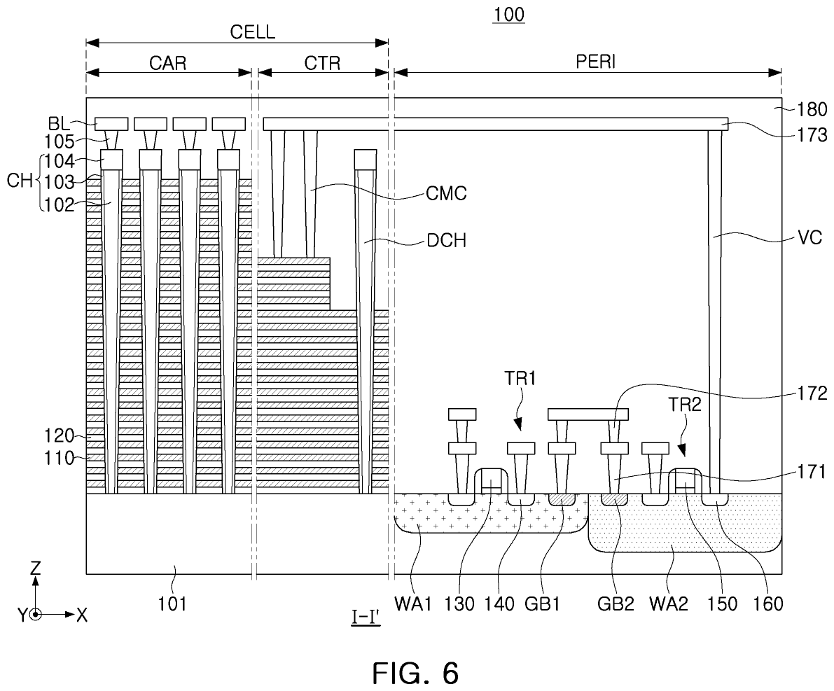

FIG. 5 is a diagram illustrating a structure of a semiconductor device according to some example embodiments of the present disclosure. Meanwhile, FIG. 6 is a view illustrating a cross-section taken along line I-I′ of the semiconductor device illustrated in FIG. 5 according to some example embodiments of the present disclosure.

In particular, FIG. 5 is a plan view illustrating a portion of a semiconductor device 100 according to some example embodiments of the present disclosure. Referring to FIG. 5, the semiconductor device 100 may include a cell region CELL and a peripheral circuit region PERI, and the cell region CELL may include a cell array region CAR and a cell contact region CTR. For example, the cell array region CAR may be a region in which channel structures CH are disposed, and the cell contact region CTR may be a region in which cell contacts CMC are disposed. In an example embodiment illustrated in FIG. 5, the cell contact region CTR may be disposed between the cell array region CAR and the peripheral circuit region PERI.

According to FIGS. 5 and 6, the cell array region CAR may include gate electrode layers 110 and insulating layers 120 stacked in a first direction (Z-axis direction) that is perpendicular to an upper surface of a substrate 101, and channel structures CH extending in the first direction and penetrating through (i.e., extending into) the gate electrode layers 110 and the insulating layers 120. Each of the channel structures CH may include a channel layer 102 connected to the substrate 101, a gate dielectric layer 103 disposed between the channel layer 102 and gate electrode layers 110, and a drain region 104. The gate dielectric layer 103 may include a tunneling layer, a charge storage layer, and a blocking layer, and at least one of the layers included in the gate dielectric layer 103 may be formed to surround the gate electrode layers 110. The drain region 104 may be connected to at least one of the bit lines BL through a bit line contact 105, and the bit lines BL may be connected to a page buffer formed in the peripheral circuit region PERI.

The cell contact region CTR may include cell contacts CMC connected to the gate electrode layers 110, and dummy channel structures DCH. The dummy channel structures DCH may have the same structure as the channel structures CH, but may not be connected to the bit lines BL, unlike the channel structures CH. For example, a page buffer formed in the peripheral circuit region PERI may be connected to the channel structures CH through the bit lines BL. The gate electrode layers 110 may form a step portion (e.g., a stepped profile) in the cell contact area CTR in at least one of a second direction (X-axis direction) or a third direction (Y-axis direction) that are parallel to an upper surface of the substrate 101, and the cell contacts CMC may be connected to the gate electrode layers 110, and may be connected to a row decoder formed in the peripheral circuit region PERI by word lines 173. The word lines 173 may be formed in an interlayer insulating layer 180 formed in the cell region CELL and the peripheral circuit region PERI.

The row decoder formed in the peripheral circuit region PERI may be disposed adjacently to the cell region CELL in the second direction. The row decoder may include first elements TR1 operating at a first power voltage, and second elements TR2 operating at a second power voltage different from the first power voltage. The first elements TR1 may be disposed in a first well region WA1, and the second elements TR2 may be disposed in a second well region WA2. The first well region WA1 may be disposed in a first position in the second direction, parallel to the upper surface of the substrate 101, and the second well region WA2 may be disposed in a second position different from the first position in the second direction. The first well region WA1 and the second well region WA2 may be disposed side by side in the second direction. That is, the first well region WA1 and the second well region WA2 may be adjacent to each other in the second direction. For example, the substrate 101 may include the first well region WA1 and the second well region WA2.

The first well region WA1 and the second well region WA2 may differ from each other in at least one of a conductivity-type of impurities or a doping concentration. In an example embodiment illustrated in FIGS. 5 and 6, the conductivity-types of the impurities of the first well region WA1 and the second well region WA2 may be identical to each other (i.e., may be the same), but the doping concentrations thereof may be different from each other. Specifically, each of the first well region WA1 and the second well region WA2 may be doped with N-type impurities. In this case, a doping concentration of the first well region WA1 may be lower than a doping concentration of the second well region WA2.

According to some example embodiments, a depth of the first well region WA1 may be shallower than a depth of the second well region WA2 (e.g., in the Z-axis direction). A second power voltage of the second elements TR2 may be lower than a first power voltage of the first elements TR1. In other words, the first elements TR1 illustrated in the example embodiments of FIGS. 5 and 6 may be high voltage PMOS elements, and the second elements TR2 may be low voltage PMOS elements. The high voltage PMOS elements included in the row decoder may be included in a high voltage switching circuit of the row decoder. The low voltage PMOS elements included in the row decoder may be included in a block decoder of the row decoder, and may be included, specifically, in an inverter of the block decoder.

Referring to FIG. 6, each of the first elements TR1 may include a gate structure 130 and a source/drain region 140, and each of the second elements TR2 may include a gate structure 150 and a source/drain region 160. At least one of the source/drain regions 160 of the second element TR2 may be connected to the wiring VC. An element contact 171 and lower wirings 172 may be connected to the source/drain regions 140 and 160, and the gate structures 130 and 150 may also be connected to gate contacts.

In an example embodiment illustrated in FIG. 6, a first well region WA1 may include a first guard band GB1, and a second well region WA2 may include a second guard band GB2. An element contact 171 and lower wirings 172 may also be connected to the first guard band GB1 and the second guard band GB2. For example, the first guard band GB1 and the second guard band GB2 may be connected to one lower wiring 172. Accordingly, the same voltage may be applied to the first guard band GB 1 and the second guard band GB2, so that a body bias voltage of the first well region WA1 may be identical to (i.e., may be the same as) a body bias voltage of the second well region WA2. For example, the body bias voltages of the first and second well regions WA1 and WA2 may be positive voltages.

Accordingly, even if a doping concentration of impurities in the first well region WA1 is different from a doping concentration of impurities in the second well region WA2, the first well region WA1 may be in contact with the second well region WA2 in the second direction. By reducing a distance between the well regions WA1 and WA2, the degree of integration of the row decoder and the peripheral circuit region PERI may be improved.

In an example embodiment illustrated in FIGS. 5 and 6, the first well region WA1 may be disposed closest to the cell region CELL in the second direction. However, this is only an example embodiment, and the first well region WA1 may be disposed furthest from the cell region CELL in the second direction.

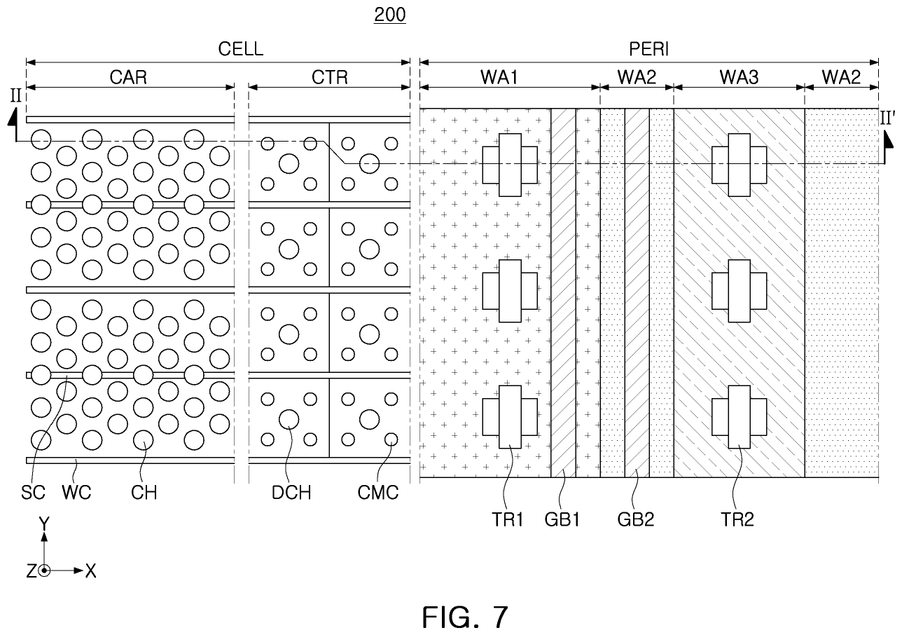

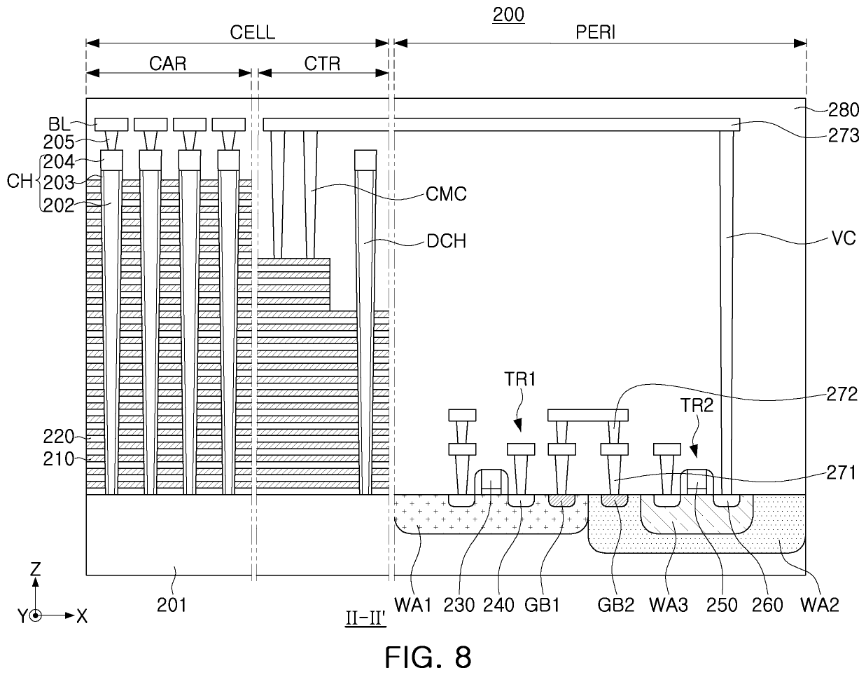

FIG. 7 is a view illustrating a structure of a semiconductor device according to some example embodiments of the present disclosure. Meanwhile, FIG. 8 is a view illustrating a cross-section taken along line II-II′ of the semiconductor device illustrated in FIG. 7 according to some example embodiments of the present disclosure.

In particular, FIG. 7 is a plan view illustrating a portion of a semiconductor device 200 according to some example embodiments of the present disclosure. Referring to FIGS. 7 and 8, the semiconductor device 200 may include a cell region CELL and a peripheral circuit region PERI, and the cell region CELL may include a cell array region CAR and a cell contact region CTR. The configuration of each of the cell array region CAR and the cell contact region CTR may be similar to that described above with reference to FIGS. 5 and 6.

A row decoder formed in the peripheral circuit region PERI may be disposed adjacently to the cell region CELL in the second direction (X-axis direction). The row decoder may include first elements TR1 operating at a first power voltage, and second elements TR2 operating at a second power voltage different from or equal to the first power voltage. The first elements TR1 may be disposed in the first well region WA1, and the second elements TR2 may be disposed in the second well regions WA2 and WA3.

The first well region WA1 may be disposed in a first position in the second direction, parallel to an upper surface of a substrate 201, and the second well regions WA2 and WA3 may be disposed in a second position different from the first position in the second direction. The first well region WA1 and the second well regions WA2 and WA3 may be disposed side by side in the second direction. That is, the first well region WA1 and the second well regions WA2 and WA3 may be adjacent to each other in the second direction. In some example embodiments, the second well regions WA2 and WA3 may include a deep-well region WA2 and a pocket P-well region WA3 disposed in the deep-well region WA2.

The first well region WA1 and the second well regions WA2 and WA3 may differ from each other in at least one of a conductivity-type of impurities or a doping concentration. In an example embodiment illustrated in FIGS. 7 and 8, the conductivity-type of impurities of the first well region WA1 and the second well regions WA2 and WA3 may be different from each other. Specifically, each of the first well region WA1 and the deep-well region WA2 may be doped with N-type impurities, and the pocket P-well region WA3 may be doped with P-type impurities. In this case, the doping concentration of the first well region WA1 may be different from the doping concentration of the deep-well region WA2. For example, the doping concentration of the first well region WA1 may be lower than a doping concentration of a region in contact with the first well region WA1 in the deep-well region WA2. Furthermore, the doping concentration of the first well region WA1 may be higher than a doping concentration of a region disposed in a lower end of the pocket P-well region WA3 in the deep-well region WA2.

According to some example embodiments, a depth of the first well region WA1 may be deeper than a depth of the pocket P-well region WA3 and may be shallower than a depth of the deep-well region WA2 (e.g., in the Z-axis direction). A second power voltage of the second elements TR2 may be higher than or equal to a first power voltage of the first elements TR1. In other words, the first elements TR1 illustrated in the example embodiments of FIGS. 7 and 8 may be high voltage PMOS elements, and the second elements TR2 may be high voltage NMOS elements. The high voltage PMOS elements and the high voltage NMOS elements included in the row decoder may be included in a high voltage switching circuit of the row decoder.

Referring to FIG. 8, each of the first elements TR1 may include a gate structure 230 and a source/drain region 240, and each of the second elements TR2 may include a gate structure 250 and a source/drain region 260. At least one of the source/drain regions 260 of the second element TR2 may be connected to the wiring VC. An element contact 271 and lower wirings 272 may be connected to source/drain regions 240 and 260, and gate structures 230 and 250 may also be connected to gate contacts.

In an example embodiment illustrated in FIG. 8, the first well region WA1 may include a first guard band GB1, and the deep-well region WA2 may include a second guard band GB2. The element contact 271 and the lower wirings 272 may also be connected to the first guard band GB1 and the second guard band GB2. For example, the first guard band GB1 and the second guard band GB2 may be connected to one lower wiring 272. Accordingly, the same voltage may be applied to the first guard band GB1 and the second guard band GB2, so that a body bias voltage of the first well region WA1 may be identical to (i.e., may be the same as) a body bias voltage of the second well region WA2 (i.e., the deep-well region WA2). For example, the body bias voltages of the first and second well regions WA1 and WA2 may be positive voltages. The body bias voltage of the pocket P-well region WA3 may be a negative voltage.

Accordingly, even if the doping concentration of impurities in the first well region WA1 is different from the doping concentration of impurities in the deep-well region WA2, the first well region WA1 may be in contact with the deep-well region WA2 in the second direction. By reducing a distance between the well regions WA1 and WA2, the degree of integration of the row decoder and the peripheral circuit region PERI may be improved.

In an example embodiment illustrated in FIGS. 7 and 8, the first well region WA1 may be disposed closest to the cell region CELL in the second direction. However, this is only an example embodiment, and the first well region WA1 may be disposed furthest from the cell region CELL in the second direction.

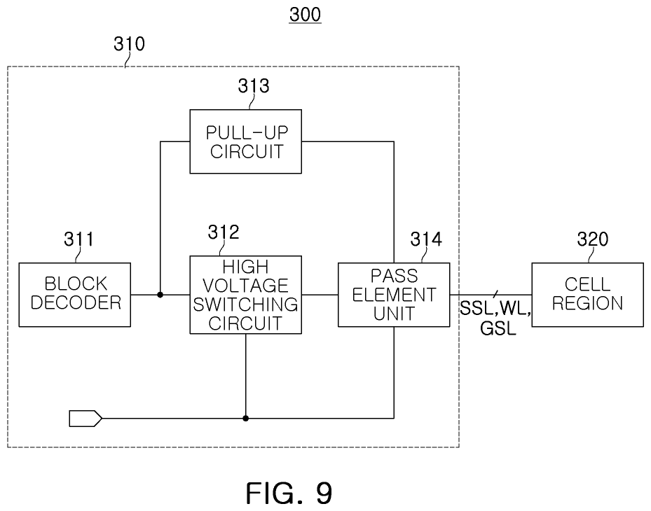

FIG. 9 is a view schematically illustrating a row decoder according to some example embodiments of the present disclosure.

Referring to FIG. 9, in a semiconductor device 300 according to some example embodiments of the present disclosure, a row decoder 310 may be connected to a cell region 320 through ground select lines GSL, word lines WL, and string select lines SSL. For example, the row decoder 310 may be electrically connected to gate electrodes of memory cells included in the cell region 320 through the ground select lines GSL, the word lines WL, and the string select lines SSL.

The row decoder 310 may include a block decoder 311, a high voltage switching circuit 312, a pull-up circuit 313, and a pass element unit 314. The block decoder 311 may be a circuit for selecting one memory block in the cell region 320. The high voltage switching circuit 312 may output a block selection signal by increasing a level of the logical value output by the block decoder 311, and pass elements included in the pass element unit 314 may be switched by the block selection signal.

The pass element unit 314 may include a plurality of pass elements connected to the cell region 320 by the ground select lines GSL, the word lines WL, and the string select lines SSL. The voltages supplied by the pass elements to the cell region 320 may generally have a relatively large level as compared to a voltage driving a circuit.

A negative voltage Vneg may be input to the high voltage switching circuit 312 and the pass element unit 314. For example, the negative voltage Vneg may be input as a body bias voltage to at least some of the elements included in the high voltage switching circuit 312 and the pass element unit 314.

In some example embodiments of the present disclosure, the row decoder 310 may include a first well region in which first elements are disposed and a second well region in which second elements are disposed. The first well region may be disposed in a first position in the second direction, parallel to an upper surface of a substrate, and the second well region may be disposed in a second position different from the first position in the second direction.

The first well region and the second well region may differ from each other in at least one of a conductivity-type of impurities or a doping concentration. In some example embodiments of the present disclosure, a body bias voltage of the first well region may be applied on the same level as a body bias voltage of the second well region, and the first well region and the second well region may be in contact with each other in the second direction.

In some example embodiments, the first elements may be high voltage PMOS elements, and the second elements may be high voltage NMOS elements. The high voltage PMOS elements included in the first elements and the high voltage NMOS elements included in the second elements may be included in a high voltage switching circuit of a row decoder (e.g., the high voltage switching circuit 312). Accordingly, the performance of the semiconductor device 300 may be improved by increasing the degree of integration of the row decoder 310 and shortening a connection path between the elements.

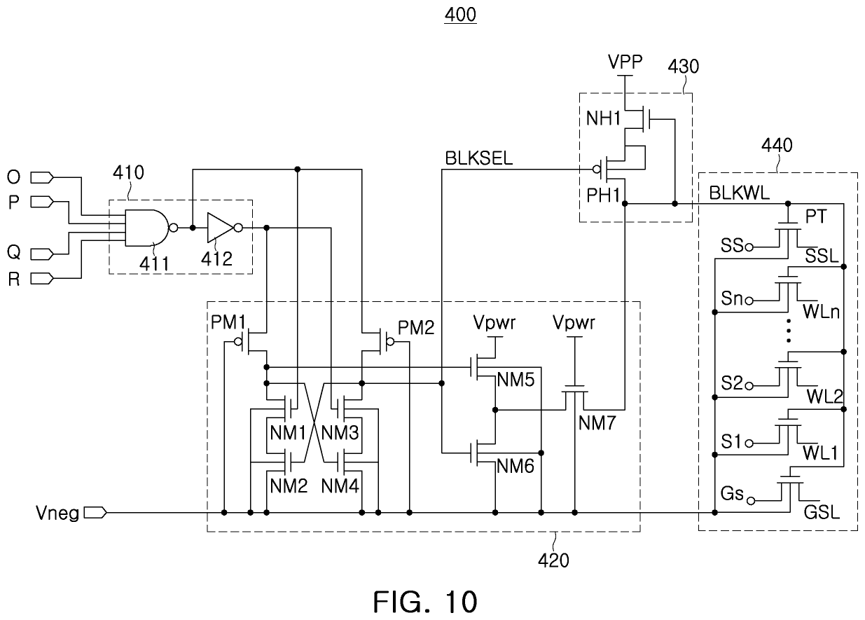

FIG. 10 is a circuit diagram schematically illustrating a row decoder according to some example embodiments of the present disclosure.

First, referring to FIG. 10, a row decoder 400 may include a block decoder 410, a high voltage switching circuit 420, a pull-up circuit 430, and a pass element unit 440. The block decoder 410 may include a NAND gate 411 and an inverter 412, and may perform NAND logic operations on decoding signals O, P, Q and R provided by a row address. For example, the block decoder 410 may further include a circuit configured to determine whether a block selected from the row address is a bad block and block an output of the NAND gate 411 according to the result of the determination. The inverter 412 may invert the output of the NAND gate 411.

The high voltage switching circuit 420 may operate in response to output signals of the NAND gate 411 and the inverter 412. The high voltage switching circuit 420 may include PMOS elements PM1 and PM2, NMOS elements NM1 to NM6, and a depletion mode NMOS element NM7.

For example, when an output of the NAND gate 411 has a low level (0), a first PMOS element PM1 may be turned on, and a second PMOS element PM2 may be turned off. Accordingly, an output of a high level Vpwr of the inverter 412 may be input to each gate of a third NMOS element NM3, a fourth NMOS element NM4, and a fifth NMOS element NM5, and the third NMOS element NM3, the fourth NMOS element NM4, and the fifth NMOS element NM5 may be turned on. Accordingly, a negative voltage Vneg may be input to a node between the third NMOS element NM3 and a sixth NMOS element NM6, and a high level Vpwr may be input to a node between a seventh NMOS element NM7 and a high voltage PMOS element PH1.

When a voltage of a node between the fifth NMOS element NM5 and the sixth NMOS element NM6 increases to a threshold voltage of the depletion mode NMOS element NM7, the depletion mode NMOS element NM7 may be shut off. Accordingly, when the output of the NAND gate 411 is on a low level, the high voltage switching circuit 420 may be electrically separated from a block word line BLKWL to which gates of pass elements PT are connected. In this case, the pass elements PT may be turned on by a high power voltage VPP input by the pull-up circuit 430 to the block word line BLKWL.

Conversely, when the output of the NAND gate 411 is on a high level Vpwr, the high voltage switching circuit 420 may be connected to the block word line BLKWL. When the output of the NAND gate 411 is on the high level Vpwr, the first PMOS element PMI may be turned off, while an output of the inverter 412 has a low level (0), thus turning on the second PMOS element PM2. Accordingly, the high level Vpwr output of the NAND gate 411 may be input to each gate of the first NMOS element NM1, the second NMOS element NM2, and the sixth NMOS element NM6, thus turning on the first NMOS element NM1, the second NMOS element NM2, and the sixth NMOS element NM6.

Since the sixth NMOS element NM6 is turned on, a negative voltage Vneg may be input to a node between the fifth NMOS element NM5 and the sixth NMOS element NM6, unlike when the output of the NAND gate 411 is on the low level (0). The negative voltage Vneg may be input to the block word line BLKWL through the depletion mode element NM7. For example, when a voltage of the block word line BLKWL is a ground voltage, the negative voltage Vneg may be input to the block word line BLKWL through the depletion mode element NM7, and when a voltage of the block word line BLKWL is a high power voltage VPP, the voltage of the block word line BLKWL may be discharged through the depletion mode element NM7.

The negative voltage Vneg may be input as a bias voltage to bodies of the pass elements PT. When the output of the NAND gate 411 is on a high level, the voltage of the block word line BLKWL connected to the gate of the pass elements PT may be reduced to the negative voltage Vneg by the high voltage switching circuit 420, thus turning off the pass elements PT. According to example embodiments, the negative voltage Vneg may be provided to at least one of a string select line SSL or a ground select line GSL. Meanwhile, in the high voltage switching circuit 420, the PMOS elements PM1 and PM2 and the first to sixth NMOS elements NM1 to NM6 may operate as level shifters.

The pull-up circuit 430 may be connected between the high power voltage VPP and the block word line BLKWL, and may input the high power voltage VPP to the block word line BLKWL in response to the output of the NAND gate 411. Referring to FIG. 10, the pull-up circuit 430 may include a depletion mode element NH1 and a high voltage PMOS element PH1. A drain of the depletion mode element NH1 may receive the high power voltage VPP, and a gate thereof may be connected to the block word line BLKWL. The drain of the high voltage PMOS element PH1 may be connected to the block word line BLKWL, and the gate thereof may be connected to a node between the third NMOS element NM3 and the sixth NMOS element NM6.

When the output of the NAND gate 411 is on the low level, the high voltage PMOS element PH1 may be turned on, and a threshold voltage of the depletion mode element NH1 may be input to the block word line BLKWL. Accordingly, the voltage of the block word line BLKWL may increase. The voltage of the block word line BLKWL may be input to the gate of the depletion mode element NH1 to turn on the depletion mode element NH1, and accordingly, the high power voltage VPP may be input to the block word line BLKWL. As described above, when the output of the NAND gate 411 is on a low level, because the high voltage switching circuit 420 is separated from the block word line BLKWL, the negative voltage Vneg may not be input to the block word line BLKWL. Accordingly, the pass elements PT may be turned on by the high power voltage VPP input to the block word line BLKWL.

On the other hand, when the output of the NAND gate 411 is on a high level, the high voltage PMOS element PH1 may be turned off, and the high power voltage VPP may not be input to the block word line BLKWL. Furthermore, as described above, when the output of the NAND gate 411 is on the high level, the high voltage switching circuit 420 may be connected to the block word line BLKWL and the negative voltage Vneg may be input to the block word line BLKWL, thus turning off the pass elements PT by the negative voltage Vneg input to the block word line BLKWL.

In the circuit diagram illustrated in FIG. 10, a negative voltage Vneg may be input as a bias voltage to a body of some NMOS elements, such as pass elements PT and first to sixth NMOS elements NM1 to NM6. According to example embodiments, the first to sixth NMOS elements NM1 to NM6 included in the high voltage switching circuit 420 may be high voltage NMOS elements. Furthermore, the PMOS elements PM1 and PM2 included in the high voltage switching circuit 420 may be high voltage PMOS elements, and the PMOS elements included in the inverter 412 of the block decoder 410 may be low voltage PMOS elements.

In some example embodiments of the present disclosure, a well region of the PMOS elements PM1 and PM2, which are high voltage PMOS elements, may be disposed to be in contact with a well region of low voltage PMOS elements included in the inverter 412. As described above with reference to FIGS. 5 and 6, the same body bias voltage may be applied to each of the well regions so that the well regions may be in contact with each other. Accordingly, an area of a region in which the row decoder 400 is disposed may be reduced, and the degree of integration of the semiconductor device including the row decoder 400 may be improved.

Furthermore, in some example embodiments of the present disclosure, the well region of the PMOS elements PM1 and PM2, which are high voltage PMOS elements, may be disposed to be in contact with a well region of the first to sixth NMOS elements NM1 to NM6, which are high voltage NMOS elements. As described above with reference to FIGS. 7 and 8, the same body bias voltage may be applied to each of the well regions so that the well regions may be in contact with each other. Accordingly, an area of a region in which the row decoder 400 is disposed may be reduced, and the degree of integration of the semiconductor device including the row decoder 400 may be improved.

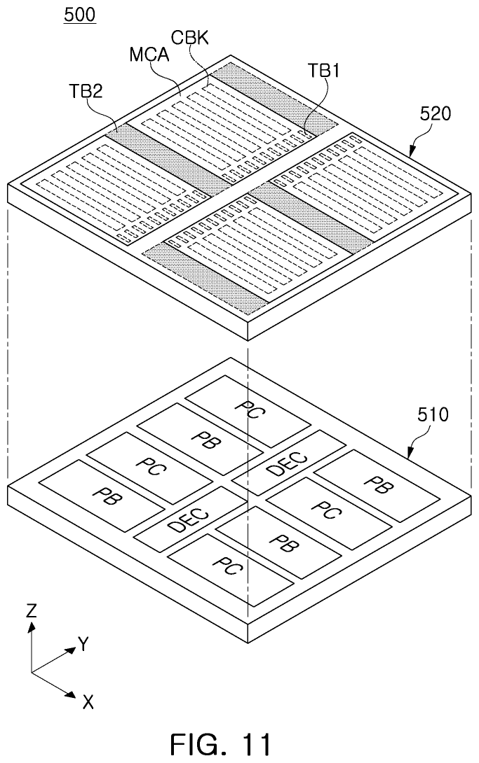

FIG. 11 is a view schematically illustrating a structure of a semiconductor device according to some example embodiments of the present disclosure.

Referring to FIG. 11, a semiconductor device 500 may include a first region 510 and a second region 520 stacked in a first direction (Z-axis direction of FIG. 11). The first region 510 may be a peripheral circuit region and may include a row decoder DEC, a page buffer PB, and a peripheral circuit PC formed on a first substrate. For example, the peripheral circuit PC may include a voltage generator, a source driver, and an input/output circuit.

The second region 520 may be a cell region, and may include memory cell arrays MCA and first and second penetration wiring regions TB1 and TB2 formed on a second substrate. In each of the first and second penetration wiring regions TB1 and TB2, penetration wiring for connecting the first region 510 and the second region 520 to each other and extending in a vertical direction (i.e., the Z-axis direction) may be disposed. Cell blocks CBK included in each of the memory cell arrays MCA may extend in the second direction (X-axis direction of FIG. 11) and may be disposed along the third direction (Y-axis direction of FIG. 11). According to example embodiments, at least one dummy block may be disposed between at least some of the cell blocks CBK.

The first region 510 may include a plurality of elements for implementing the row decoder DEC, the page buffer PB and the peripheral circuit PC included in the peripheral circuit region, and wiring patterns connected to the elements, and the elements may be divided into low voltage elements and high voltage elements according to a power voltage required for operations. For example, the plurality of elements may provide the row decoder DEC, the page buffer PB and the peripheral circuit PC included in the peripheral circuit region.

In some example embodiments, high voltage PMOS elements among the high voltage elements may be formed in a first well region doped with N-type impurities, and low voltage PMOS elements among the low voltage elements may be formed in a second well region doped with N-type impurities. A doping concentration of the first well region may be lower than a doping concentration of the second well region. The same body bias voltage may be applied to the first well region having the high voltage PMOS elements formed therein and the second well region having the low voltage PMOS elements formed therein, and the first well region and the second well region may be in contact with each other in the second direction.

Furthermore, in some example embodiments, the high voltage PMOS elements among the high voltage elements may be formed in a first well region doped with the N-type impurities. Meanwhile, high voltage NMOS elements among the high voltage elements may be formed in the second well region, and the second well region may include a deep-well region doped with the N-type impurities, and a pocket P-well region disposed in the deep-well region and doped with P-type impurities. The second well region may be surrounded by a third well region doped with the N-type impurities. In other words, at least one of the high voltage PMOS elements may be disposed in the first well region, and at least one of the high voltage NMOS elements may be disposed in the pocket P-well region, but a separate device may not be disposed in the deep-well region. In other words, the deep-well region may be free of a separate device. The same body bias voltage may be applied to the first well region having the high voltage PMOS elements formed therein and the deep-well region that is free of the elements, and the first well region and the deep-well region may be in contact with each other in the second direction.

In other words, the well regions doped with the N-type impurities among the elements formed in the first region 510 may be brought into contact in the second direction. Accordingly, a distance between the well regions may be eliminated, and the degree of integration of the elements may be improved.

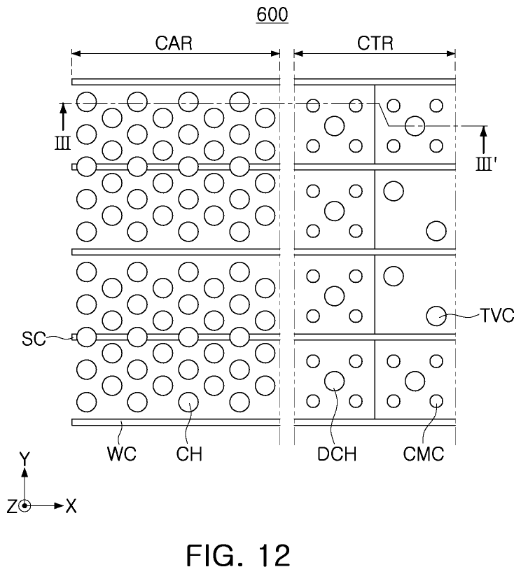

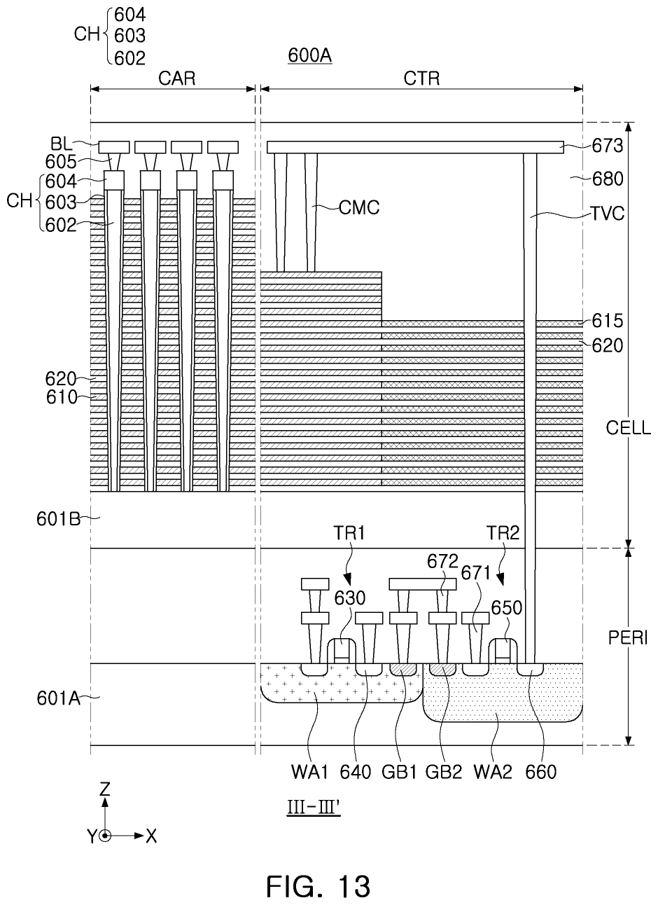

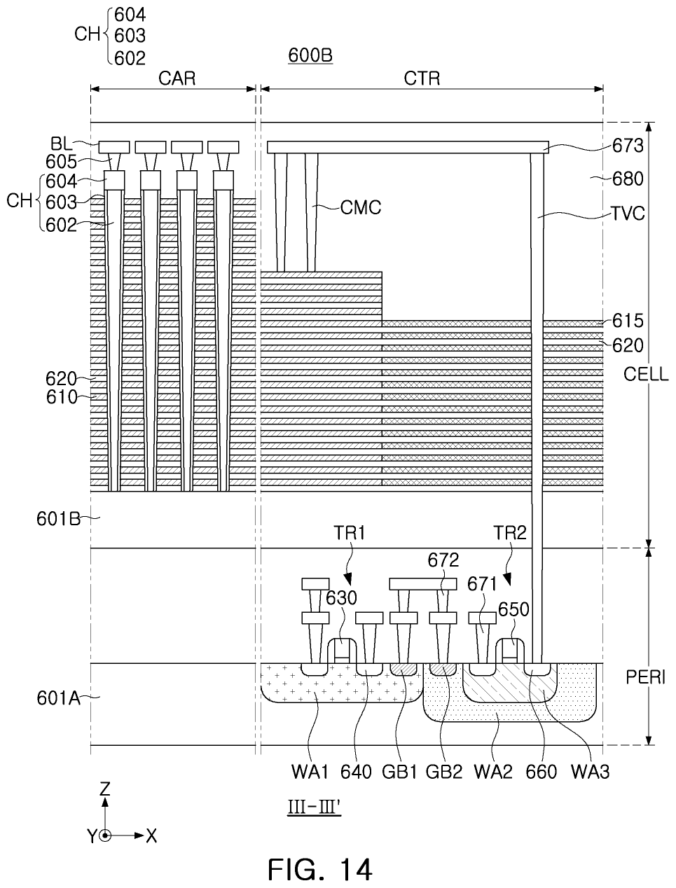

FIG. 12 is a view illustrating a structure of a semiconductor device according to some example embodiments of the present disclosure. FIGS. 13 and 14 are views illustrating a cross-section taken along line III-III′ of the semiconductor device of FIG. 12 according to some example embodiments of the present disclosure.

Referring to FIGS. 12 to 14, a cell region CELL and a peripheral circuit region PERI may be stacked in the first direction (Z-axis direction). The cell region CELL of a semiconductor device 600 may include a cell array region CAR and a cell contact region CTR. For example, the cell array region CAR may be a region in which channel structures CH are disposed, and the cell contact region CTR may be a region in which cell contacts CMC are disposed.

The peripheral circuit region PERI may include a first substrate 601A, a plurality of elements TR1 and TR2 formed on the first substrate 601A, and wiring patterns 671 and 672 connected to the plurality of elements TR1 and TR2. The wiring patterns 671 and 672 may include an element contact 671 and lower wirings 672. A first element TR1 may include a gate structure 630 and a source/drain region 640. A second element TR2 may include a gate structure 650 and a source/drain region 660.

The cell array region CAR may include gate electrode layers 610 and insulating layers 620 stacked in a first direction perpendicular to an upper surface of a second substrate 601B (i.e., a Z-axis direction), and channel structures CH penetrating through (i.e., extending into) the gate electrode layers 610 and insulating layers 620. A structure of the channel structures CH may be similar to that described above with reference to FIGS. 5 and 6.

Meanwhile, the cell contact region CTR may include cell contacts CMC and penetration wiring TVC connected to the gate electrode layers 610. In a region in which the penetration wiring TVC is disposed, sacrificial layers 615 may remain without being replaced with the gate electrode layers 610. Accordingly, the penetration wiring TVC may be separated from the gate electrode layers 610, and may penetrate through (i.e., extend into) the sacrificial layers 615 and the insulating layers 620 to be connected to the elements TR1 and TR2 of the peripheral circuit region PERI disposed in a lower portion of the cell contact region CTR.

In an example embodiment illustrated in FIG. 13, the second element TR2 having the source/drain region 660 connected to the penetration wiring TVC may be one of the elements included in the row decoder in the peripheral circuit region PERI. As described above with reference to FIGS. 5 and 6, the first element TR1 may be a high voltage PMOS, and the second element TR2 may be a low voltage PMOS. By applying the same body bias voltage to well regions WA1 and WA2, doped with N-type impurities, of the high voltage PMOS and the low voltage PMOS, a first well region WA1 of the first element TR1 may be disposed to be in contact with a second well region WA2 of the second element TR2 in the second direction (X-axis direction). Accordingly, the degree of integration of a semiconductor device 600A may be improved.

In an example embodiment illustrated in FIG. 14, the second element TR2 having the source/drain region 660 connected to the penetration wiring TVC may be one of the elements included in the row decoder in the peripheral circuit region PERI. As described above with reference to FIGS. 7 and 8, the first element TR1 may be a high voltage PMOS, and the second element TR2 may be a high voltage NMOS. By applying the same body bias voltage to well regions WA1 and WA2, doped with N-type impurities, of the high voltage PMOS and the low voltage PMOS, a first well region WA1 of the first element TR1 and a deep-well region WA2 of the second element TR2 may be disposed to be in contact with each other. Accordingly, the degree of integration of a semiconductor device 600B may be improved.

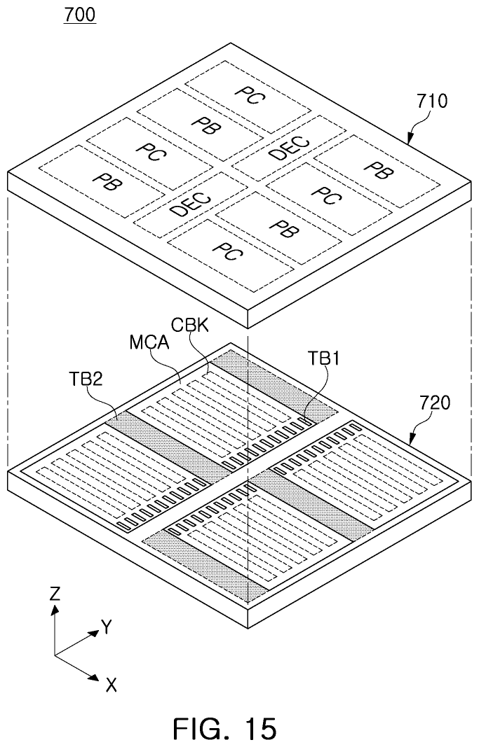

FIG. 15 is a view schematically illustrating a structure of a semiconductor device according to some example embodiments of the present disclosure.

Referring to FIG. 15, a semiconductor device 700 may include a first region 710 and a second region 720 stacked in the first direction (Z-axis direction of FIG. 15). The first region 710 may be a peripheral circuit region, and the second region 720 may be a cell region. The configurations of each of the first region 710 and the second region 720 may be similar to that of the first region 510 and the second region 520 described above with reference to FIG. 11.

However, unlike the example embodiment described with reference to FIG. 11, in an example embodiment illustrated in FIG. 15, the first region 710 including the peripheral circuit region may be coupled to the second region 720 in a state in which the first region 710 is inverted. Accordingly, elements included in the first region 710 and providing a row decoder DEC, a page buffer PB and a peripheral circuit PC, and gate electrode layers, channel structures and bit lines included in the second region 720 may be disposed between a first substrate of the first region 710 and a second substrate of the second region 720 in the first direction.

The elements disposed in the first region 710 may include high voltage elements and low voltage elements. At least some of the high voltage PMOS elements belonging to the high voltage elements may be disposed with a well region thereof in contact with a well region of some of the low voltage PMOS and/or high voltage NMOS elements. In this case, each of the contacted well regions may be doped with N-type impurities, but doping concentrations thereof may be different from each other. In other words, the same body bias voltage may be applied to the contacted well regions, and the well regions may be disposed to be in contact with each other without a distance between the well regions. Accordingly, the degree of integration of the semiconductor device 700 may be improved.

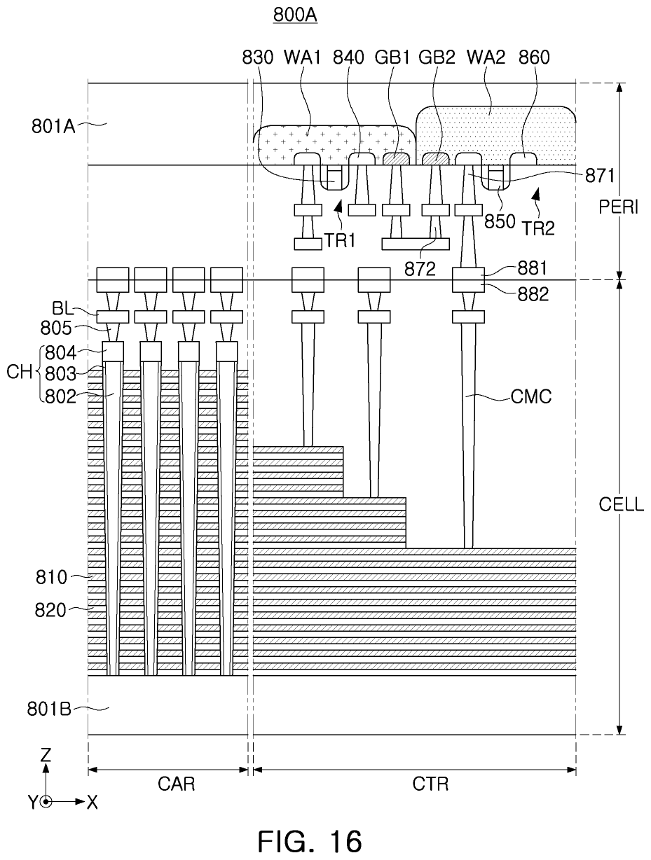

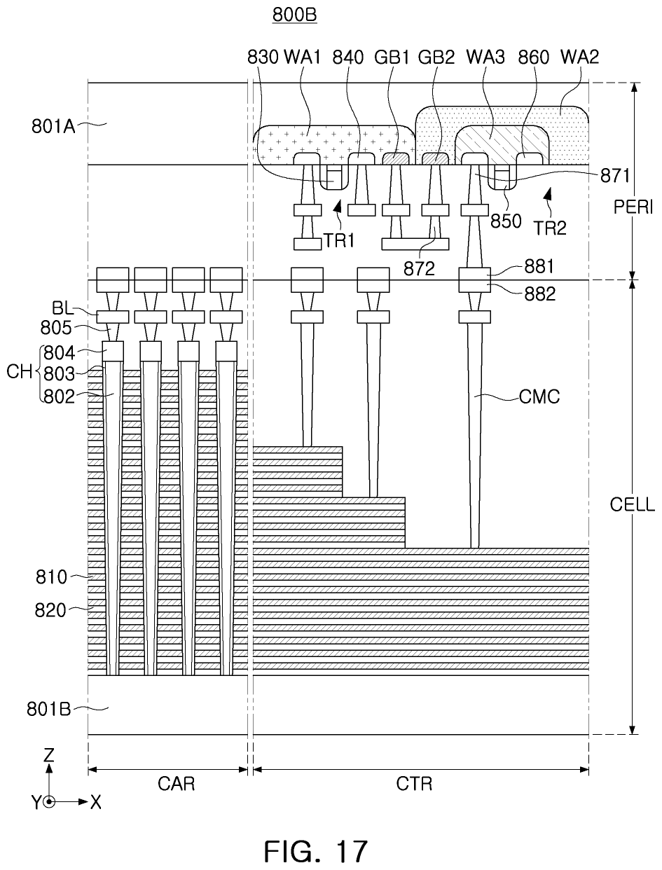

FIGS. 16 and 17 are views illustrating a structure of a semiconductor device according to some example embodiments of the present disclosure.

Referring to FIGS. 16 and 17, semiconductor devices 800A and 800B may include a cell region CELL and a peripheral circuit region PERI stacked in the first direction (Z-axis direction). However, unlike the example embodiments described with reference to FIGS. 13 and 14, the peripheral circuit region PERI may be stacked with the cell region CELL in a state in which the peripheral circuit region PERI is inverted. Accordingly, elements TR1 and TR2 of the peripheral circuit region PERI, gate electrode layers 810 of the cell region CELL, and channel structures CH may be disposed between a first substrate 801A of the peripheral circuit region PERI and a second substrate 801B of the cell region CELL. The plurality of elements TR1 and TR2 may be formed on the first substrate 801A. The second substrate 801B may be stacked with the peripheral circuit region PERI in the first direction.

For example, the semiconductor devices 800A and 800B may have a chip-to-chip (C2C) structure. The C2C structure may refer to a structure in which a first chip including the peripheral circuit region PERI is manufactured on a first wafer, a second chip including the cell region CELL is manufactured on a second wafer different from the first wafer, and then the first chip and the second chip are connected to each other by a bonding manner. For example, the bonding manner may refer to a manner of physically and electrically connecting a bonding pad formed on an uppermost wiring pattern layer of the first chip and a bonding pad formed on an uppermost wiring pattern layer of the second chip. For example, when the bonding pad is formed of copper (Cu), the bonding method may be a Cu—Cu bonding method. However, the present disclosure is not limited thereto, and for example, the bonding pad may be formed of aluminum or tungsten.

The peripheral circuit region PERI may include a plurality of elements TR1 and TR2 and wiring patterns 871 and 872 connected to the plurality of elements TR1 and TR2. The wiring patterns 871 and 872 may include an element contact 871 and lower wirings 872. The lower wirings 872 may be connected to a bonding pad 881 for coupling the cell region CELL and the peripheral circuit region PERI.

The cell region CELL may include a cell array region CAR and a cell contact region CTR. The cell array region CAR may be a region in which channel structures CH are disposed, and the cell contact region CTR may be a region where cell contacts CMC are disposed. The cell array region CAR may include gate electrode layers 810 and insulating layers 820, channel structures CH penetrating through (i.e., extending into) the gate electrode layers 810 and the insulating layers 820, and bit lines BL connected to the channel structures CH, which are stacked in the first direction, perpendicular to an upper surface of the second substrate 801B. For example, the channel structures CH may extend in the first direction and may be connected to the second substrate 801B. A structure of the channel structures CH may be similar to that described above with reference to FIGS. 5 and 6. The cell contact region CTR may include cell contacts CMC connected to the gate electrode layers 810.

The bit lines BL and the cell contacts CMC may be connected to a bonding pad 882 formed on an upper portion of the cell region CELL. As described above, the bonding pad 881 of the peripheral circuit region PERI and the bonding pad 882 of the cell region CELL may be connected to each other by a bonding manner.

In order to efficiently connect the peripheral circuit region PERI and the cell region CELL, an arrangement of circuits included in the peripheral circuit region PERI may be determined by an arrangement of the cell array region CAR and the cell contact region CTR. For example, a page buffer connected to the channel structures CH through bit lines BL may be disposed in a region that is stacked with the cell array region CAR and that is in the peripheral circuit region PERI. Furthermore, a row decoder connected to the gate electrode layers 810 may be disposed in a region that is stacked with the cell contact region CTR and that is in the peripheral circuit region PERI.

The elements disposed in the peripheral circuit region PERI may include high voltage elements and low voltage elements. Configurations of each of the first element TR1 and the second element TR2 according to example embodiments illustrated in FIGS. 16 and 17 may be similar to those described with reference to FIGS. 13 and 14, respectively. In other words, at least some of the high voltage PMOS elements may be disposed with a well region thereof in contact with a well region of some of the low voltage PMOS and/or high voltage NMOS elements. In this case, each of the contacted well regions may be doped with N-type impurities, but doping concentrations thereof may be different. In other words, the same body bias voltage may be applied to the contacted well regions, and the well regions may be disposed to be in contact with each other without a distance between the well regions. Accordingly, the degree of integration of the semiconductor devices 800A and 800B may be improved.

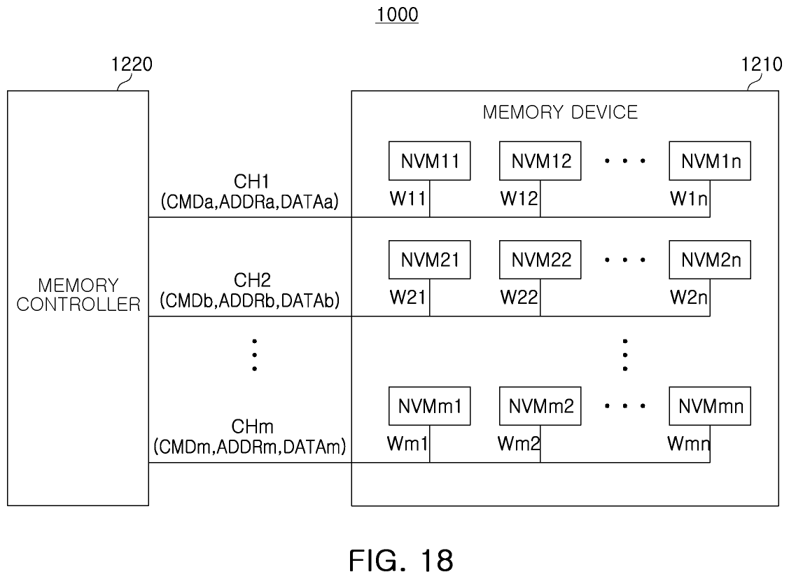

FIG. 18 is a block diagram schematically illustrating a storage device including a semiconductor device according to some example embodiments of the present disclosure.

Referring to FIG. 18, a memory system 1000 may include a memory device 1210 and a memory controller 1220. The memory system 1000 may support a plurality of channels CH1 to CHm, and the memory device 1210 and the memory controller 1220 may be connected through the plurality of channels CH1 to CHm. For example, the memory system 1000 may be implemented as a storage device such as a solid state drive (SSD).

The memory device 1210 may include a plurality of memory devices NVM11 to NVMmn. Each of the memory devices NVM11 to NVMmn may be connected to one of the plurality of channels CHI to CHm through a corresponding way. For example, memory devices NVM11 to NVMIn may be connected to a first channel CHI through ways W11 to W1n, and memory devices NVM21 to NVM2n may be connected to a second channel CH2 through ways W21 to W2n. In some example embodiments, each of the memory devices NVM11 to NVMmn may be implemented in any memory unit that may operate according to an individual command from the memory controller 1220. For example, each of the memory devices NVM11 to NVMmn may be implemented as a chip or a die, but the present disclosure is not limited thereto.

The memory controller 1220 may transmit or receive signals to or from the memory device 1210 through the plurality of channels CH1 to CHm. For example, the memory controller 1220 may transmit commands CMDa to CMDm, addresses ADDRa to ADDRm, and data DATAa to DATAm to the memory device 1210 through the channels CH1 to CHm, or receive data DATAa to DATAm from the memory device 1210.

The memory controller 1220 may select one of nonvolatile memory devices connected to a corresponding channel through each channel, and may transmit or receive signals to or from the selected nonvolatile memory device. For example, the memory controller 1220 may select a nonvolatile memory device NVM11 from memory devices NVM11 to NVM1n connected to the first channel CH1. The memory controller 1220 may transmit a command CMDa, an address ADDRa, and data DATAa to the selected memory device NVM11, or may receive the data DATAa from the selected memory device NVM11.

The memory controller 1220 may transmit or receive signals in parallel to or from the memory device 1210 through different channels. For example, the memory controller 1220 may transmit a command CMDb to the memory device 1210 through the second channel CH2 while transmitting the command CMDa to the memory device 1210 through the first channel CH1. For example, the memory controller 1220 may receive data DATAb from the memory device 1210 through the second channel CH2 while receiving the data DATAa from the memory device 1210 through the first channel CH1.

The memory controller 1220 may control an overall operation of the memory device 1210. The memory controller 1220 may control each of the memory devices NVM11 to NVMmn connected to the channels CH1 to CHm by transmitting signals to the channels CH1 to CHm. For example, the memory controller 1220 may control one of the memory devices NVM11 to NVM1n by transmitting the command CMDa and the address ADDRa to the first channel CH1.

Each of the memory devices NVM11 to NVMmn may operate under the control of the memory controller 1220. For example, a memory device NVM11 may write the data DATAa according to the command CMDa, the address ADDRa, and the data DATAa provided to the first channel CH1. For example, a memory device NVM21 may read the data DATAb according to the command CMDb and the address ADDRb provided to the second channel CH2, and transmit the read data DATAb to the memory controller 1220.

FIG. 18 illustrates that the memory device 1210 communicates with the memory controller 1220 through m channels, and the memory device 1210 includes n non-volatile memory devices corresponding to each channel, but the number of channels and the number of non-volatile memory devices connected to a single channel may be variously changed.

The memory device 1210 and the memory controller 1220 may be implemented as a semiconductor device according to some example embodiments of the present disclosure. For example, in the memory device 1210 and the memory controller 1220, at least some of the high voltage PMOS elements among the high voltage elements may be disposed with a well region thereof in contact with a well region of some of the low voltage PMOS and/or high voltage NMOS elements. In this case, the contacted well regions may be doped with N-type impurities, and the same body bias voltage may be applied to the contacted well regions. Accordingly, the degree of integration of the memory device 1210 and the memory controller 1220 may be improved, and operation performance thereof may also be improved.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

The present disclosure is not limited to the example embodiments described above, and it is possible to appropriately change without departing from the scope of the present disclosure. That is, the present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device comprising:
a peripheral circuit region including a plurality of elements on a substrate, the plurality of elements providing a page buffer and a row decoder; and
a cell region including gate electrode layers and channel structures, wherein the gate electrode layers are stacked in a first direction perpendicular to an upper surface of the substrate and are connected to the row decoder, and wherein the channel structures extend into the gate electrode layers in the first direction and are connected to the page buffer,
wherein the peripheral circuit region includes a first well region and a second well region, and at least one of a conductivity-type of impurities or a doping concentration of the first well region is different from that of the second well region,
wherein the row decoder includes at least one first element among the plurality of elements in the first well region, and at least one second element among the plurality of elements in the second well region,
wherein the first well region and the second well region are configured to have a same body bias voltage, and
wherein the first well region and the second well region are adjacent to each other in a second direction parallel to the upper surface of the substrate, and the first well region is in contact with the second well region in the second direction.

2. The semiconductor device of claim 1, wherein each of the first well region and the second well region is doped with N-type impurities.

3. The semiconductor device of claim 2, wherein the doping concentration of the first well region is lower than a doping concentration of the second well region.

4. The semiconductor device of claim 2, wherein a depth of the first well region in the first direction is shallower than a depth of the second well region in the first direction.

5. The semiconductor device of claim 2, wherein a body bias voltage of the first well region and a body bias voltage of the second well region are positive voltages.

6. The semiconductor device of claim 2, wherein the at least one first element is configured to operate at a first power voltage, and
wherein the at least one second element is configured to operate at a second power voltage lower than the first power voltage.

7. The semiconductor device of claim 1, wherein the second well region comprises a deep-well region in contact with the first well region in the second direction, and a pocket P-well region in the deep-well region,
wherein each of the first well region and the deep-well region is doped with N-type impurities, and
wherein the first well region and the deep-well region are configured to have the same body bias voltage.

8. The semiconductor device of claim 7, wherein the doping concentration of the first well region is different from a doping concentration of the deep-well region.

9. The semiconductor device of claim 7, wherein a depth of the first well region in the first direction is deeper than a depth of the pocket P-well region in the first direction and is shallower than a depth of the deep-well region in the first direction.

10. The semiconductor device of claim 7, wherein a body bias voltage of the first well region and a body bias voltage of the deep-well region are positive voltages, and
wherein a body bias voltage of the pocket P-well region is a negative voltage.

11. The semiconductor device of claim 7, wherein the at least one first element is configured to operate at a first power voltage, and
wherein the at least one second element is configured to operate at a second power voltage higher than or equal to the first power voltage.

12. The semiconductor device of claim 1, wherein the substrate is a first substrate,
wherein the cell region includes a second substrate stacked with the peripheral circuit region in the first direction,
wherein the channel structures extend in the first direction and are connected to the second substrate, and
wherein the plurality of elements, the gate electrode layers, and the channel structures are between the first substrate and the second substrate in the first direction.

13. A semiconductor device comprising:
a peripheral circuit region including a substrate and first and second elements on the substrate, wherein the substrate comprises a first well region doped with a first concentration of impurities having a first conductivity-type and a second well region doped with a second concentration of impurities having a second conductivity-type; and
a cell region including gate electrode layers and channel structures, wherein the gate electrode layers are stacked in a first direction perpendicular to an upper surface of the substrate, and wherein the channel structures extend into the gate electrode layers in the first direction,
wherein the first well region and the second well region are configured to have a same body bias voltage, and
wherein the first well region is in contact with the second well region in a second direction parallel to the upper surface of the substrate.

14. The semiconductor device of claim 13, wherein each of the first conductivity-type and the second conductivity-type is N-type, and
wherein the first concentration of impurities is lower than the second concentration of impurities.

15. The semiconductor device of claim 13, wherein a body bias voltage of the first well region and a body bias voltage of the second well region are positive voltages.

16. The semiconductor device of claim 13, wherein at least one of the first elements is in the first well region, and at least one of the second elements is in the second well region, and
wherein a power voltage higher than that of the at least one of the second elements is configured to be applied to the at least one of the first elements.

17. The semiconductor device of claim 13, wherein at least one of the first elements is in the first well region, and the second well region is free of the second elements.

18. A semiconductor device comprising:
a substrate including a first well region and a second well region, wherein at least one of a conductivity-type of impurities or a doping concentration of the first well region is different from that of the second well region;
a plurality of first elements in the first well region; and
a plurality of second elements in the second well region,
wherein the first well region and the second well region are configured to have a same body bias voltage, and
wherein the first well region is in contact with the second well region.

19. The semiconductor device of claim 18, wherein each of the first well region and the second well region is doped with N-type impurities,
wherein the doping concentration of the first well region is lower than a doping concentration of the second well region, and
wherein a body bias voltage of the first well region and a body bias voltage of the second well region are positive voltages.

20. The semiconductor device of claim 18, wherein the second well region comprises a deep-well region in contact with the first well region in a second direction parallel to an upper surface of the substrate, and a pocket P-well region in the deep-well region,
wherein each of the first well region and the deep-well region is doped with N-type impurities,
wherein the doping concentration of the first well region is different from a doping concentration of the deep-well region,
wherein a body bias voltage of the first well region and a body bias voltage of the deep-well region are positive voltages, and
wherein a body bias voltage of the pocket P-well region is a negative voltage.
